(19) United States
(12) Patent Application Publication
(10) Pub. No.: US 2014/0217525 A1
(43) Pub. Date: Aug. 7, 2014

(54) METHOD OF IMPROVING SENSITIVITY OF TERRESTRIAL MAGNETISM SENSOR AND APPARATUS USING THE SAME

(71) Applicant: SAMSUNG ELECTRO-MECHANICS CO., LTD., Suwon (KR)

(72) Inventors: Sung Ho Lee, Suwon (KR); Boum Seock Kim, Suwon (KR); Eun Tae Park, Suwon (KR); Se Hoon Jeong, Suwon (KR)

(73) Assignee: SAMSUNG ELECTRO-MECHANICS CO., LTD., Suwon (KR)

(21) Appl. No.: 13/949,135

(22) Filed: Jul. 23, 2013

(30) Foreign Application Priority Data
Feb. 6, 2013 (KR) 10-2013-0013306

(51) Int. Cl. H01L 43/14; H01L 43/06

(52) U.S. Cl. CPC H01L 43/14; H01L 43/065
USPC 257/421; 438/3

(57) ABSTRACT

Disclosed herein are a method of improving sensitivity of a terrestrial magnetism sensor and an apparatus using the same. A method of forming a terrestrial magnetism sensor includes: cleaning a surface of the terrestrial magnetism sensor; and depositing a thermoelectric material as a thin film on the cleaned surface of the terrestrial magnetism sensor. Therefore, a sensing error of the terrestrial magnetism sensor that has been generated due to heat in the prior art is decreased, thereby making it possible to allow the terrestrial magnetism sensor to calculate an accurate sensing value.

### CROSS REFERENCE TO RELATED APPLICATION

This application claims the benefit of Korean Patent Application No. 10-2013-0013306, filed on Feb. 6, 2013, entitled “The Method of Improving Sensitivity of Terrestrial Magnetism Sensor and Apparatus Using the Same”, which is hereby incorporated by reference in its entirety into this application.

### BACKGROUND OF THE INVENTION

1. Technical Field

The present invention relates to a method of improving sensitivity of a terrestrial magnetism sensor and an apparatus using the same.

2. Description of the Related Art

Various sensors have been used in a smart phone. Recently, in accordance with the prevalent use of the iPhone by Apple, Inc and the Galaxy series by Samsung Electronics, daily lives of persons have become more convenient. For example, an acceleration sensor, a terrestrial magnetism sensor, a gyro sensor, and the like, may be mounted in the smart phone to perform a function such as a game, position tracking, navigation, or the like. Particularly, the terrestrial magnetism sensor embedded in the smart phone is a sensor that may overcome a disadvantage of position tracking in a global positioning system (GPS) scheme. Therefore, many studies on the terrestrial magnetism sensor have been conducted.

An example of a general terrestrial magnetism sensor for applying an electronic compass includes a magnetic resonance (MR) effect sensor, a fluxgate sensor, a magneto-impedance sensor, a resonator sensor based on the Lorentz's force, a hall sensor, and the like. All of these sensors have been developed so as to have improved precision and resolution, be miniaturized, be manufactured at a low cost, and be driven with low power. Among them, the hall sensor is mainly mounted in the smart phone.

Since a geomagnetic field sensed by the terrestrial magnetism sensor is 0.5 to 0.60e, which is very small, a design robust to an external magnetic field, a temperature, and an external environment is required. Currently, many terrestrial magnetism sensor manufacturers have made an effort to solve this problem.

The following Prior Art Document (Patent Document: JP2003-065791), which relates to a method of measuring an azimuth of a hall sensor, has disclosed a method of correcting a sensed value and calculating an orientation based on the corrected value.

### PRIOR ART DOCUMENT

### Patent Document

(Patent Document 1) JP2003-065791

### SUMMARY OF THE INVENTION

The present invention has been made in an effort to provide an apparatus of improving sensing performance of a terrestrial magnetism sensor.

Further, the present invention has been made in an effort to provide a method of improving sensing performance of a terrestrial magnetism sensor.

According to a preferred embodiment of the present invention, there is provided a method of forming a terrestrial magnetism sensor, the method including: cleaning a surface of the terrestrial magnetism sensor; and depositing a thermoelectric material as a thin film on the cleaned surface of the terrestrial magnetism sensor.

The method may further include reforming the surface of the terrestrial magnetism sensor.

The depositing of the thermoelectric material as the thin film on the cleaned surface of the terrestrial magnetism sensor may include selectively depositing the thermoelectric material as the thin film on only a specific portion of the surface of the terrestrial magnetism sensor in which sensing is performed.

The terrestrial magnetism sensor may be a hall sensor. As the thermoelectric material, a Bi₂Te₃ based material may be used at a temperature of 400K or less, a Zn₄Sb₃ or PbTe based material may be used at a temperature from above 400K to 700K or less, an Mg₂Si or CoSb₃ based material may be used at a temperature from above 700K to 850K or less, and an SiGe based material may be used at a temperature above 850K, according to a temperature at which the terrestrial magnetism sensor is operated.

The depositing of the thermoelectric material as the thin film on the cleaned surface of the terrestrial magnetism sensor may include: adjusting at least one of a temperature of the surface of the terrestrial sensor, a magnitude of electrical energy by electrodes, a concentration of an introduced gasified thermoelectric material, and a distance between the electrodes and the surface of the terrestrial magnetism sensor to determine a thickness of the thin film deposited on the terrestrial magnetism sensor; and depositing the thermoelectric material as the thin film on the cleaned surface of the terrestrial magnetism sensor according to the determined thickness of the thin film.

According to another preferred embodiment of the present invention, there is provided a terrestrial magnetism sensor including: a hall sensor measuring an external geomagnetic field; and a thin film deposited based on a thermoelectric material on a surface of the hall sensor.

The thin film may be formed by cleaning a surface of the terrestrial magnetism sensor, reforming the surface of the terrestrial magnetism sensor, and depositing the thermoelectric material on the cleaned surface of the terrestrial magnetism sensor.

The thin film may be deposited on only a specific portion of the surface of the terrestrial magnetism sensor in which sensing is performed.

As the thermoelectric material, a Bi₂Te₃ based material may be used at a temperature of 400K or less, a Zn₄Sb₃ or PbTe based material may be used at a temperature from above 400K to 700K or less, an Mg₂Si or CoSb₃ based material may be used at a temperature from above 700K to 850K or less, and an SiGe based material may be used at a temperature above 850K, according to a temperature at which the terrestrial magnetism sensor is operated.

A thickness at which the thin film is deposited may be determined by adjusting at least one of a temperature of the surface of the terrestrial sensor, a magnitude of electrical energy by electrodes, a concentration of an introduced gasified thermoelectric material, and a distance between the electrodes and the surface of the terrestrial magnetism sensor.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a conceptual diagram showing a method of decreasing an error due to a temperature in a terrestrial magnetism according to a preferred embodiment of the present invention;

FIG. 2 is a conceptual diagram for describing a hall effect according to the preferred embodiment of the present invention;

FIG. 3 is a flow chart showing a method of forming a thin film pattern on the terrestrial magnetism sensor according to the preferred embodiment of the present invention;

FIG. 4 is a conceptual diagram showing a method of depositing a thermoelectric material on a surface of the terrestrial magnetism sensor; and

FIGS. 5A and 5B are conceptual diagrams showing the terrestrial magnetism sensor on which a thin film is mounted according to the preferred embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

A terrestrial magnetism sensor may measure a geomagnetic field, which is one of the micro magnetic fields, to measure an orientation. The terrestrial magnetism sensor may sense the orientation by measuring a three-axis component of the geomagnetic field at a position horizontal to the Earth's surface.

One of the largest problems of the terrestrial magnetism sensor is a problem of compensating for a measuring error due to a temperature. Currently, the terrestrial magnetism sensor mounted in a device such as a smart phone has used a method of correcting an error of the terrestrial magnetism sensor generated due to the temperature by separately mounting a temperature sensor in the smart phone. However, even though the temperature sensor is mounted in the smart phone, output values of the terrestrial magnetism sensor should be corrected so as to correspond to the respective temperature values. A process of correcting measured values calculated by the terrestrial magnetism sensor based on the temperature values to obtain accurate measured values is not algorithmically easy.

Even though the error of the measured values of the terrestrial magnetism sensor is corrected, since corrected data are only corrected values, it is difficult to consider the corrected values as accurate sensor data. Therefore, in the present invention, a method of improving precision of the terrestrial magnetism sensor so that values sensed by the terrestrial magnetism sensor may be output as constant values without being affected by a temperature or an external environment factor will be disclosed.

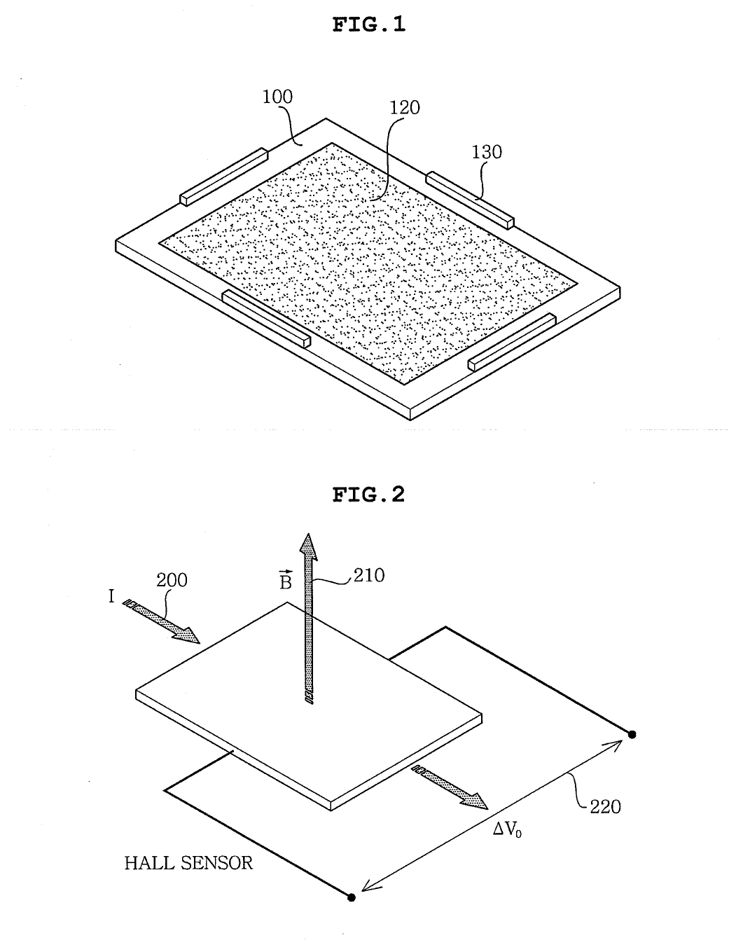

FIG. 1 is a conceptual diagram showing a method of decreasing an error due to a temperature in a terrestrial magnetism according to a preferred embodiment of the present invention.

In FIG. 1, a method of implementing a terrestrial magnetism sensor by patterning a thermoelectric element is shown. The terrestrial magnetism sensor may be configured of electrodes 130, a hall sensor 100, and a thermoelectric material 120 patterned as a thin film in the terrestrial magnetism sensor.

The hall sensor, which is one of the terrestrial magnetism sensors, is a sensor sensing a geomagnetic field using a hall effect. Since the hall sensor 100 may be manufactured at a size smaller and in a structure simpler than those of other terrestrial magnetism sensors, it may be mainly used as a terrestrial magnetism sensor for a small sized device such as a smart phone.

The thin film 120 indicates a thermoelectric element deposited by various thin film processes such as a physical vapor deposition (PVD) process, a chemical vapor deposition (CVD) process, and the like. The electrode 130 may be implemented in order to generate a current and a magnetic field to sense a flow of the current. Although the case in which the thin film is deposited over the entire one surface of the terrestrial magnetism sensor (hall sensor) is shown in FIG. 1, the thin film is not limited to being deposited on the entire surface of the terrestrial magnetism sensor, but may also be mounted on a portion of the terrestrial magnetism sensor, which is included in the scope of the present invention.

Hereinafter, in the preferred embodiment of the present invention, a sensing process of a hall sensor and a thin film forming process will be described in more detail.

FIG. 2 is a conceptual diagram for describing a hall effect according to the preferred embodiment of the present invention.

Referring to FIG. 2, the hall effect is an effect in which the Lorentz's force is applied to an electron due to a magnetic field 210 generated from the outside and a movement direction of the electron 200 is bent. In the case in which the movement direction of the electron 200 is bent by the magnetic field 210, a measured voltage 220 may be changed. Therefore, the terrestrial magnetism sensor may measure strength of the external magnetic field 210 by measuring the change in the voltage 220 using the hall effect.

That is, since the hall effect in which the direction of the current is bent by the geomagnetic field is generated and the change in the voltage 220 is generated according to the bent direction of the current 200, the terrestrial magnetism sensor using the hall sensor may measure a magnitude of the geomagnetic field based on the change in the voltage 220. The sensor using the hall effect as described above may have disadvantages such as an influence due to an external interference magnetic field, a temperature drift, an offset voltage, and the like.

According to the preferred embodiment of the present invention, in order to decrease an error due to a temperature, which is the largest error among errors generated in the terrestrial magnetism sensor using the hall effect, the thermoelectric material may be patterned as the thin film on the surface of the terrestrial magnetism sensor.

A thermoelectric phenomenon indicates an energy conversion phenomenon that heat may be converted into electricity or the electricity may be converted into the heat, and the thermoelectric material indicates a material in which the thermoelectric phenomenon is generated. As the thermoelectric material, various materials may be used according to a temperature. For example, a Bi₂Te₃ based material may be used at a temperature of 400K or less, a Zn₄Sb₃ or PbTe based material may be used at a temperature from above 400K to 700K or less, an Mg₂Si or CoSb₃ based material may be used at a temperature from above 700K to 850K or less, and an SiGe based material may be used at a temperature above 850K.

The thermoelectric effect may be represented by the following Equation 1.

$$α = \frac{Δ V}{Δ T} [ μ V / K ] \qquad 〈 Equation 1 〉$$

Where α, which is a value called a Seebeck coefficient, means a voltage induced from a unit temperature difference. Generally, the Seebeck coefficient has a very small value corresponding to about several μV/K in a metal and has a value of about several hundreds of μV/K in a semiconductor. The larger the value of the Seebeck coefficient, the larger the electromotive force generated by the thermoelectric effect. Therefore, a material having the large Seebeck coefficient may become a thermoelectric material having excellent performance.

Meanwhile, a value called ZT is used as an index for judging characteristics of each material used as the thermoelectric material. In the case in which a temperature difference is present, when a temperature of a low temperature portion is TL, a temperature of a high temperature portion is TH, thermal conductivity of a material used for the thermoelectric effect is K, and electrical conductivity of the material is σ, ZT may be represented by the following Equation 2.

$$ZT = \frac{{α}^{2} σ T}{κ} \qquad 〈 Equation 2 〉$$

Where T indicates an average temperature of the high temperature portion and the low temperature portion. That is, T=(TH+TL)/2. Referring to the above Equation 2, ZT is a value that is in proportion to the square of the Seebeck coefficient. Therefore, in order to improve the thermoelectric effect, the larger the value of the Seebeck coefficient, the better.

That is, the thermoelectric material, which is a material high electrical conductivity but bad thermal conductivity, is ideal in the case in which it has high ZT. Silicon, which is a semiconductor material that is generally widely used, has electrical conductivity of 150 W/cm²K. Therefore, ZT of the silicon at a room temperature is only 0.01. Meanwhile, ZT of Bi₂Te₃ that is widely used is close to 1 at a room temperature.

According to the preferred embodiment of the present invention, the thermoelectric element having the high electrical conductivity and the low thermal conductivity as described above is patterned as a thin film on the hall sensor, thereby making it possible to prevent generation of the error in the sensor due to the temperature. That is, when a terrestrial magnetism sensor chip is manufactured, the thermoelectric material is patterned as the thin film to constantly maintain a temperature of a surface of the sensor chip, thereby making it possible to decrease an error of a magnetic field measuring value sensed and output by the terrestrial magnetism sensor.

The terrestrial magnetism sensor using the hall effect uses a semiconductor material. Performance of the terrestrial magnetism sensor may be recognized by the following Equation 3.

V_{y}=E_{y}w=(R_{H}I/t)B <Equation 3>

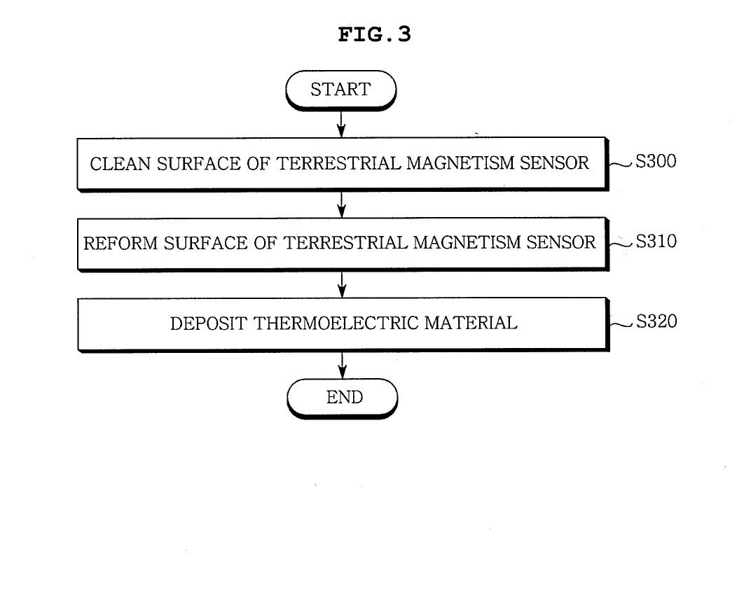

Referring to FIG. 3, it may be appreciated that a voltage output from the sensor is in proportion to a magnitude (B) of a magnetic field, a hall coefficient (R_{H}), and a current (I) and is in inverse proportion to a thickness (t) of the sensor. Particularly, the voltage depends on a carrier concentration among physical properties of a material, and the carrier concentration is sensitive to a temperature in the semiconductor material. Therefore, in order to improve performance of a hall effect sensor intended to be manufactured, it is necessary to precisely adjust a surrounding temperature of a place at which the hall effect sensor is used. It is a very important factor in determining the performance of the hall effect sensor to adjust the temperature as described above, that is, to maintain a constant temperature state.

In the case of implementing the terrestrial magnetism sensor using the thin film thermoelectric device patterned as suggested in the present invention, the terrestrial magnetism sensor is always maintained at a constant temperature, such that an output value of the terrestrial magnetism sensor according to a temperature change may be constantly maintained, which allows accurate data to be obtained, thereby making it possible to increase accuracy of position based recognition.

FIG. 3 is a flow chart showing a method of forming a thin film pattern on the terrestrial magnetism sensor according to the preferred embodiment of the present invention.

The thin film indicates a film of which a ratio to a surface area to a volume is high and has a thickness of several nm to several μm. The thin film may be deposited on the surface of the terrestrial magnetism sensor by various processes such as a thermal growing process, a physical vapor deposition (PVD) process, a chemical vapor deposition (CVD) process, and the like. The thin film is very sensitive to characteristics of the surface of the terrestrial magnetism sensor on which it is deposited and is sensitive to a thermal reaction.

When the thin film formed of the thermoelectric element is mounted on the surface of the terrestrial magnetism sensor, adhesive force between an object on which the thin film is deposited and the thermoelectric element is an important matter in improving reliability of the thin film. When the thin film is deposited on the terrestrial magnetism sensor and heat treatment is performed on the terrestrial magnetism sensor in a state in which the thin film becomes loose due to weak adhesive force, a problem may occur in performance of the terrestrial magnetism sensor. Therefore, the adhesive force between the thin film and the terrestrial magnetism sensor should be increased before the heat treatment is performed.

That is, optimal surface roughness also has an influence on the adhesive force. When the surface is excessively flat, a problem may occur in the adhesive force, and when the surface is excessive rough, a coating defect may be generated, which leads to failure of adhesion. Therefore, in the case in which the thermoelectric material is deposited as the thin film on the terrestrial magnetism sensor, a material at a portion of the terrestrial magnetism sensor on which the thermoelectric material is deposited should be implemented as a material that may increase close adhesive force of the thin film in order to increase the adhesive force of the thin film.

In addition, reliability of the adhesive force of the thin film may depend on cleanness of the surface of the terrestrial magnetism sensor on which the thin film is deposited.

As a method of depositing the thermoelectric material on the terrestrial magnetism sensor according to the preferred embodiment of the present invention, various methods such as a chemical vapor deposition method, a physical vapor deposition method, and the like, may be used.

In the chemical vapor deposition method, deposition may be performed using a method in which a fluid encloses a solid object and a reaction is then performed, such that the entire surface is doped without directivity, as in the case in which a surface of a cold object is blackened when the cold object is put into a flame.

In the physical vapor deposition method, a mechanical or thermodynamic method is used in order to obtain the thin film from a solid material. When energy or heat is applied to material to be deposited, small particles are separated from the surface. When the particles collide with a cold surface, the particles lose their energy to form a solid layer. This process is performed in a chamber in a vacuum state, such that the particles may freely move in a space in the chamber. Since the particles tend to move in a straight line direction, a film deposited by the physical vapor deposition method may be generally deposited in a state in which it has directivity.

Hereinafter, although the case in which the thin film is formed on the terrestrial magnetism sensor by a vacuum deposition method is disclosed in the preferred embodiment of the present invention for convenience of explanation, the thin film may also be formed on the terrestrial magnetism sensor by various chemical or physical vapor deposition methods described above.

First, in order to deposit the thermoelectric material on the terrestrial magnetism sensor, the surface of the terrestrial magnetism sensor may be cleaned (S300).

In the case in which the thermoelectric material is deposited on only a portion of the surface of the terrestrial magnetism sensor, only the portion of the terrestrial magnetism sensor on which the thermoelectric material is deposited may be cleaned. Impurities present in the portion at which the thin film is formed may have a large influence on adhesive force of the thin film. Therefore, the surface of the terrestrial magnetism sensor is cleaned before the thin film is formed, thereby making it possible to increase close adhesive force of the thin film. As a cleaning method, various cleaning methods such as a physical cleaning method, a chemical cleaning method, a dry cleaning method, and the like, may be used.

In the case in which the surface of the terrestrial magnetism sensor is made of a material having insufficient close adhesive force at the time of depositing the thermoelectric material thereon, an additional surface reforming process is performed, thereby making it possible to allow the thermoelectric material to be satisfactorily deposited on the terrestrial magnetism sensor (S310).

As the surface reforming process, various processes may be used. For example, a thermochemical process such as nitriding or plasma heat treatment, a surface reforming process using an ion beam, a surface reforming process using laser or an electron beam, a doping process, or the like, may be performed as the surface reforming process. That is, in a method of improving performance of a terrestrial magnetism sensor according to the preferred embodiment of the present invention, the surface reforming process is performed on the surface of the terrestrial magnetism sensor, thereby making it possible to increase an adhesive rate of the thermoelectric material at the time of performing a thin film process of the thermoelectric material.

After the surface reforming process is finished, a process of implementing the thermoelectric element as a thin film may be further performed in Step S320 to form the terrestrial magnetism sensor.

Only one of the process of cleaning the surface of the terrestrial magnetism sensor of Step S300 and the surface reforming process of the terrestrial magnetism sensor of Step S310 may be performed, which is included in the scope of the present invention.

The thermoelectric material is deposited (S320).

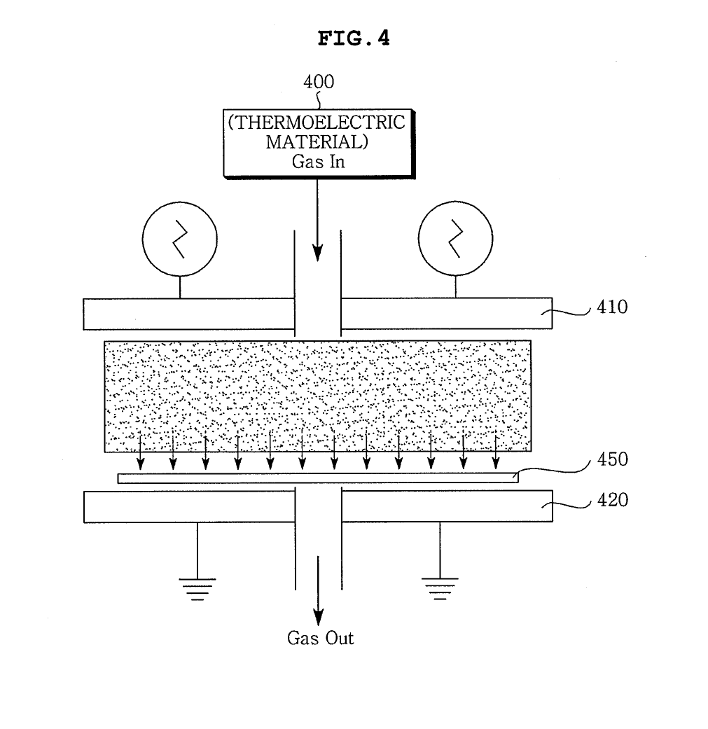

A gas phase thermoelectric material may be deposited as the thin film on the surface of the terrestrial magnetism sensor of which the cleaning is finished. Various methods may be used in order to deposit the thermoelectric material on the terrestrial magnetism sensor. Although one of the methods for depositing the thermoelectric material on the terrestrial magnetism sensor will be described by way of example with reference to FIG. 4, various methods as well as the method described with reference to FIG. 4 may be used, which is included in the scope of the present invention.

FIG. 4 is a conceptual diagram showing a method of depositing a thermoelectric material on a surface of the terrestrial magnetism sensor.

Referring to FIG. 4, a gas phase thermoelectric material 400 may be introduced into a chamber on which electrical energy generated using predetermined electrodes 410 and 420 and pressure act. The gas phase thermoelectric material 400 reacts to a surface of a terrestrial magnetism sensor 450 in the chamber configured of the predetermined electrodes, such that a thin film may be formed on a surface of the terrestrial magnetism sensor 450.

In order to allow the thermoelectric material 400 to satisfactorily react to the surface of the terrestrial magnetism sensor 450 in the chamber at the time of depositing the thermoelectric material 400 on the terrestrial magnetism sensor 450, various variables such as a temperature of the surface of the terrestrial magnetism sensor 450, a magnitude of the electrical energy, a concentration of the introduced gasified thermoelectric material, a distance between the electrodes 410 and 420 and the surface of the terrestrial magnetism sensor 450, and the like, are appropriately adjusted, thereby making it possible to allow the thin film to be uniformly formed at an appropriate thickness.

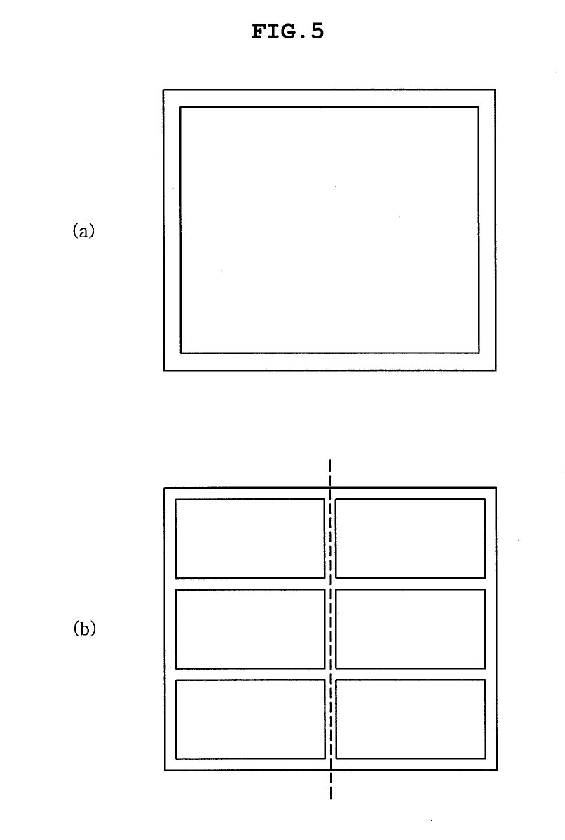

FIGS. 5A and 5B are conceptual diagrams showing the terrestrial magnetism sensor on which a thin film is mounted according to the preferred embodiment of the present invention.

FIGS. 5A and 5B show various types of thin films formed on the terrestrial magnetism sensor.

FIG. 5A shows the case in which the thin film is formed over the entire one surface of the terrestrial magnetism sensor. FIG. 5B shows the case in which the thin film is formed on one surface of the terrestrial magnetism sensor so as to have predetermined sections. That is, the thin film is not formed over the entire one surface of the terrestrial magnetism sensor, but may also be deposited on only a portion of the terrestrial magnetism sensor that has an influence on performance of the terrestrial magnetism sensor.

That is, at the time of implementing the terrestrial magnetism sensor according to the preferred embodiment of the present invention, the thermoelectric material may be deposited as the thin film on the entire surface of the hall sensor or be deposited as the thin film on only a portion of the surface of the hall sensor so as to have predetermined sections.

In the case of using the terrestrial magnetism sensor according to the preferred embodiment of the present invention, since the temperature needs not to be corrected, a compensation value is not required in an algorithm and software (S/W), such that a sensing speed may be improved as compared with an existing terrestrial magnetism sensor. In addition, since power required for operating a temperature sensor is not consumed, a power saving effect is generated in a device using a battery having a limited capacity, such as a smart phone, such that a driving time of the smart phone may be increased.

As set forth above, in the method of improving sensitivity of a terrestrial magnetism sensor and an apparatus using the same according to the preferred embodiments of the present invention, the thermoelectric material is patterned and deposited on the terrestrial magnetism sensor to decrease a sensing error of the terrestrial magnetism sensor that has been generated due to heat in the prior art, thereby making it possible to allow the terrestrial magnetism sensor to calculate an accurate sensing value.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A method of forming a terrestrial magnetism sensor, the method comprising:
cleaning a surface of the terrestrial magnetism sensor; and
depositing a thermoelectric material as a thin film on the cleaned surface of the terrestrial magnetism sensor.

2. The method as set forth in claim 1, further comprising reforming the surface of the terrestrial magnetism sensor.

3. The method as set forth in claim 1, wherein the depositing of the thermoelectric material as the thin film on the cleaned surface of the terrestrial magnetism sensor includes selectively depositing the thermoelectric material as the thin film on only a specific portion of the surface of the terrestrial magnetism sensor in which sensing is performed.

4. The method as set forth in claim 1, wherein the terrestrial magnetism sensor is a hall sensor.

5. The method as set forth in claim 1, wherein as the thermoelectric material, a Bi₂Te₃ based material is used at a temperature of 400K or less, a Zn₄Sb₃ or PbTe based material is used at a temperature from above 400K to 700K or less, an Mg₂Si or CoSb₃ based material is used at a temperature from above 700K to 850K or less, and an SiGe based material is used at a temperature above 850K, according to a temperature at which the terrestrial magnetism sensor is operated.

6. The method as set forth in claim 1, wherein the depositing of the thermoelectric material as the thin film on the cleaned surface of the terrestrial magnetism sensor includes:
adjusting at least one of a temperature of the surface of the terrestrial sensor, a magnitude of electrical energy by electrodes, a concentration of an introduced gasified thermoelectric material, and a distance between the electrodes and the surface of the terrestrial magnetism sensor to determine a thickness of the thin film deposited on the terrestrial magnetism sensor; and
depositing the thermoelectric material as the thin film on the cleaned surface of the terrestrial magnetism sensor according to the determined thickness of the thin film.

7. A terrestrial magnetism sensor comprising:
a hall sensor measuring an external geomagnetic field; and
a thin film deposited based on a thermoelectric material on a surface of the hall sensor.

8. The terrestrial magnetism sensor as set forth in claim 7, wherein the thin film is formed by cleaning a surface of the terrestrial magnetism sensor, reforming the surface of the terrestrial magnetism sensor, and depositing the thermoelectric material on the cleaned surface of the terrestrial magnetism sensor.

9. The terrestrial magnetism sensor as set forth in claim 7, wherein the thin film is deposited on only a specific portion of the surface of the terrestrial magnetism sensor in which sensing is performed.

10. The terrestrial magnetism sensor as set forth in claim 7, wherein as the thermoelectric material, a Bi₂Te₃ based material is used at a temperature of 400K or less, a Zn₄Sb₃ or PbTe based material is used at a temperature from above 400K to 700K or less, an Mg₂Si or CoSb₃ based material is used at a temperature from above 700K to 850K or less, and an SiGe based material is used at a temperature above 850K, according to a temperature at which the terrestrial magnetism sensor is operated.

11. The terrestrial magnetism sensor as set forth in claim 7, wherein a thickness at which the thin film is deposited is determined by adjusting at least one of a temperature of the surface of the terrestrial sensor, a magnitude of electrical energy by electrodes, a concentration of an introduced gasified thermoelectric material, and a distance between the electrodes and the surface of the terrestrial magnetism sensor.
